(19) United States
(12) Patent Application Publication
(10) Pub. No.: US 2010/0265671 A1
(43) Pub. Date: Oct. 21, 2010

(54) PACKAGE STRUCTURE OF PRINTED CIRCUIT BOARD AND PACKAGE METHOD THEREOF

(75) Inventors: CHIA-HSI TSAI, TAIPEI CITY (TW); CHENG-TE TSENG, TAIPEI CITY (TW); TZU-KAN CHEN, TAIPEI CITY (TW); YI-TING LIN, TAIPEI CITY (TW)

Correspondence Address: RABIN & Berdo, PC, 1101 14TH STREET, NW, SUITE 500, WASHINGTON, DC, 20005, US

(73) Assignees: SILITEK ELECTRONIC (GUANGZHOU) CO., LTD., Guangzhou (CN); LITE-ON TECHNOLOGY CORPORATION, Taipei City (TW)

(21) Appl. No.: 12/537,441

(22) Filed: Aug. 7, 2009

(30) Foreign Application Priority Data
Apr. 16, 2009 (CN) 200910038769.1

(51) Int. Cl. H05K 1/00; H05K 3/00

(52) U.S. Cl. 361/749; 361/748; 29/829

(57) ABSTRACT

The package structure of the PCB comprises a substrate and a frame. The frame is located at the top of the substrate, and the substrate and the frame define a receiving space. The electronic components are mounted on the substrate and distributed in the receiving space. Because of the protection of the frame, the electronic components are effectively protected from the collision of installation in the process or use in the process. The substrate can be a flexible circuit board or a rigid-flex PCB and the electronic components are directly embedded in the substrate. Therefore the thickness of the package structure is reduced.

### BACKGROUND OF THE INVENTION

1. Field of the Invention

The present invention relates to a package structure of printed circuit board and a package method thereof, in particular to a package structure with improved protection for electronic components and a package method thereof.

2. Description of Related Art

The PCB of a lens module is used for carrying the electronic component and there are usually many electronic components disposed on the PCB. In traditional, there is a receiving room formed on the PCB usually by an excavating method to accommodate the electronic components. However, the traditional manufacturing method is complex and it causes the broken failure of PCB. On the other hand, some electronic components are higher than the PCB because of the different heights of the electronic components. Thus, the higher components are easily departed from the substrate due to the collision.

In another traditional method, a frame is attached on the substrate by gluing method. There is misaligned error between the frame and the substrate when the frame is glued on the substrate. On the other hand, the structure strength of glued structure is low so that the frame easily departs from the substrate. Moreover, the heat generated in welding process to weld the electronic components results in the over-flow of the glue and the structural strength is decreased.

On the other hand, a harder board, such as a rigid-flex board or a ceramic board is necessary used when the substrate is a kind of flex and soft board with deformation issue. Therefore, the total thickness of the package structure is large due to the usage of the harder board. The manufacturing method of the package structure is more complex.

Therefore, in view of this, the inventor proposes the present invention to overcome the above problems based on his expert experience and deliberate research.

### SUMMARY OF THE INVENTION

The primary objective of the present invention is to provide a package structure with stable structure and the manufacturing method of the package structure is simplified.

To achieve the above-mentioned objective, the present invention provides a package structure. The package structure of printed circuit board includes a substrate and a frame. The frame is disposed on the substrate to form a receiving space, and a plurality of electronic components is mounted on the substrate and received inside the receiving space. The frame is rectangular and the height of the rectangular frame is higher than or equal to that of each electronic component.

The frame is aligned to the peripheral edges of the substrate. Alternatively, the frame extends to the sides of the substrate and partially covers the sides of the substrate, or extends to the bottom of the substrate. The frame has a plurality of conductive hole portions and the conductive hole portions connect electrically to the substrate.

The package structure has the following advantages:

1. The structural strength of the package structure is improved. The frame is used for defining the receiving space which the electronic components are accommodated thereinside so that the thickness of the PCB can be reduced. Furthermore, the supporting area and the strength are improved. On the other hand, the manufacturing yield is increased and the manufacturing cost is decreased. The electronic components which are mounted on the substrate and received in the receiving space can be protected by the frame from the collision in the installation or application. The electronic components can be also prevented from the contamination of the welding material. In another embodiment, a receiving hole can be formed on the flex substrate for accommodating the electronic components and the frame can be formed to package and to fix the electronic components with the substrate. Therefore, the structure is simplified and the thickness of the package structure is reduced.

2. The frame is fixed to the substrate with high adhesive strength because the frame is formed by the insert-molding method. The disconnection issue of the frame and the substrate is solved, which is resulted from the glue adhesion. Moreover, the high-temperature over-flow problem of glue when the electronic component is welded on the substrate is also solved. Therefore, the manufacturing efficiency and the manufacturing yield are highly improved. In addition, the manufacturing cost is reduced.

In order to further understand the techniques, means, and effects that the present invention takes for achieving the prescribed objectives, the following detailed descriptions and appended drawings are hereby referred; such that, through which the purposes, features, and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIG. 1 shows the first embodiment of the package structure according to the present invention.

FIGS. 2A to 2B show the first package method of the first embodiment of the package structure according to the present invention.

FIG. 2C shows the second package method of the first embodiment of the package structure according to the present invention.

FIGS. 3A to 3D show the package method of the second embodiment of the package structure according to the present invention.

FIG. 3E shows the explored view of the second embodiment of the package structure according to the present invention.

### DETAILED DESCRIPTION OF THE PREFERRED EMBODIMENTS

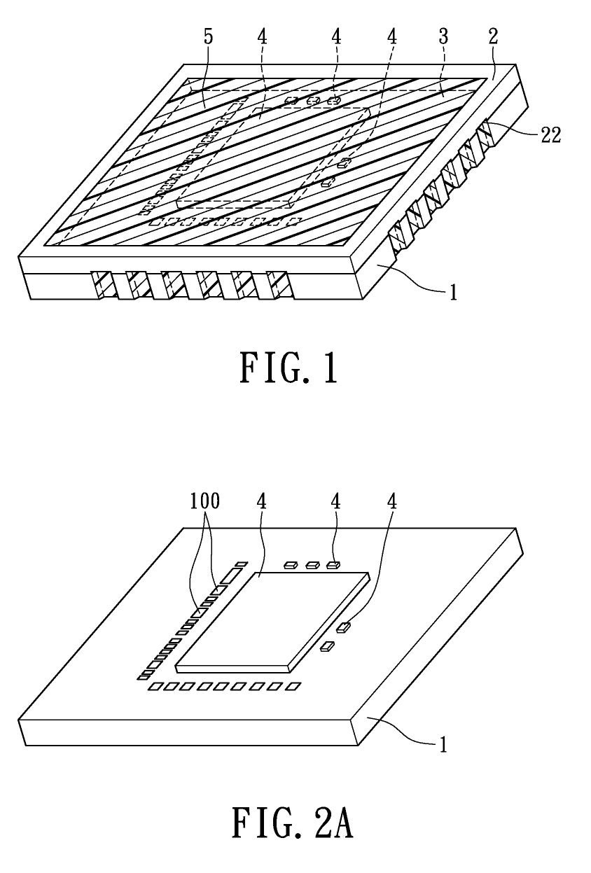

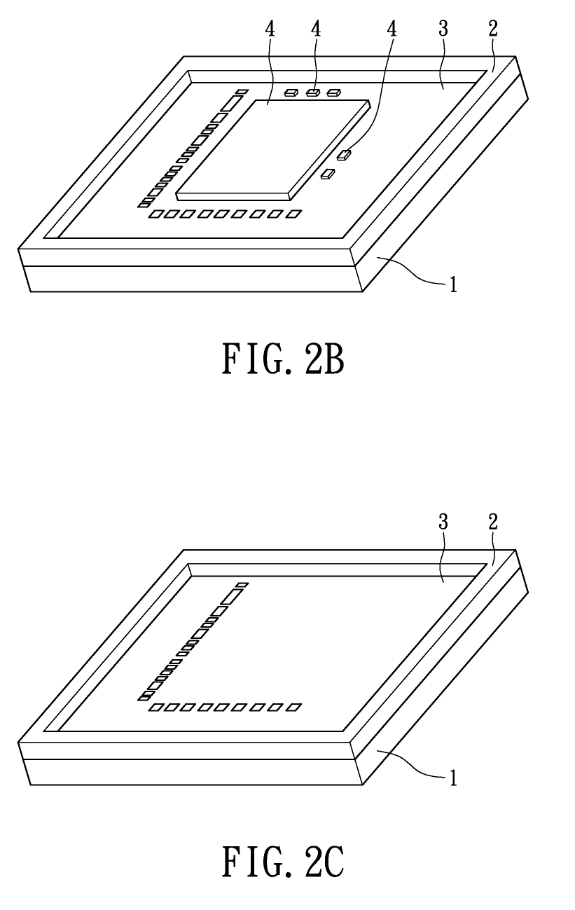

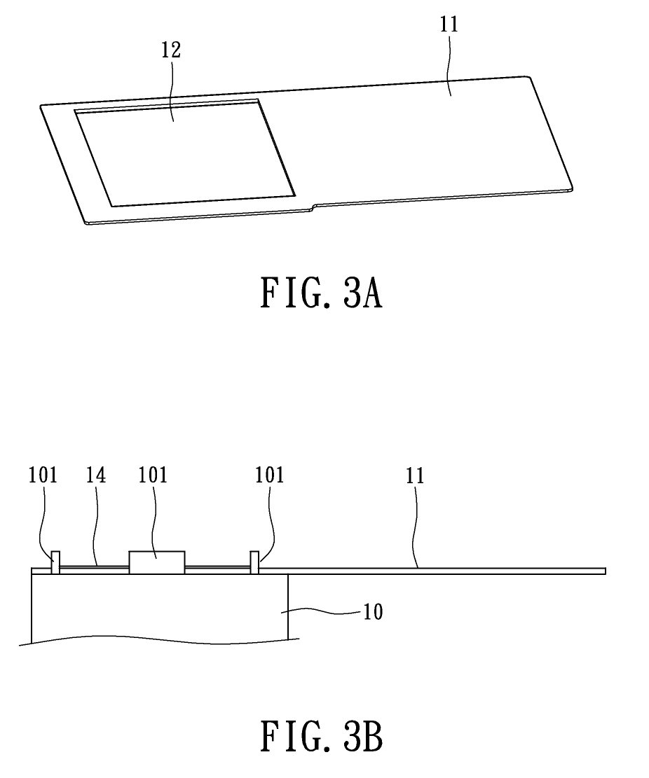

Please refer to FIG. 1 and FIGS. 2A to 2B; the present invention provides a package structure of printed circuit board, and the package structure includes a substrate 1 and a frame 2. The substrate 1 and the frame 2 are fixed together. The substrate 1 is used to carry electronic components 4. The frame 2 is fixed on the substrate 1 so as to form a receiving space 3. Therefore, the electronic components 4 are disposed on the substrate 1 and received in the receiving space 3.

The substrate 1 has a plurality of welding pads thereon for electrically connecting the electronic components 4 with the substrate 1. The electronic components 4 can be mounted on the substrate 1 by conduction wires, BGA package (ball gate array) or another connection method. In the embodiment, the electronic components 4 are connected electrically to the welding pads of the substrate 1 by gold wires. The amount and the size of electronic components 4 can be chosen depending on the practical demand or the size of the substrate 1 and the size of the receiving space 3. The shape of the substrate 1 is not limited, for example, the shape of the substrate 1 can be a rectangle, a diamond shape (rhombus), a square shape, or another shape. Moreover, the substrate 1 can be a printed circuit board (PCB), a flex printed circuit (FPC) board, a rigid flex board, or a ceramic board.

The electronic components 4 can be one kind of or various kinds of active components or passive components, such as resistances, capacitors, inductances, transformers, and sensors. On the other hand, the above-mentioned sensor can be CCD or CMOS.

The frame 2 is made of thermoplastic materials and it shows dark color in the embodiment. As shown in FIG. 1, the frame 2 is aligned to the peripheral edges of the substrate 1. Alternatively, the frame 2 extends to the sides of the substrate 1 and partially covers the sides of he substrate 1, or extends to the bottom of the substrate 1. Thus, the frame 2 is formed around the electronic components 4. In the embodiment, the frame 2 is a frame with four sides and has a plurality of conductive hole portions 22. The conductive hole portions 22 connect electrically to the substrate 1. The conductive hole portions 22 can be formed by etching and deposition processes (i.e., electro-plating, or chemical-plating). In other words, the frame 2 is aligned to the peripheral edges of the substrate 1, or extends on the sides of the substrate 1 and partially covers the sides of the substrate 1, or extends to the bottom of the substrate 1. Therefore, the receiving space 3 is formed by the substrate 1 and the frame 2. In the embodiment, the receiving space 3 is rectangle-shaped and the electronic components 4 are received inside the receiving space 3. Furthermore, the height of the frame 2 is higher than or equal to the height of each electronic component 4. Thus, the electronic components 4 which are mounted on the substrate 1 and received in the receiving space 3 can be protected by the frame 2.

FIG. 1 shows a first embodiment. The package structure includes an encapsulating structure 5 which is made of thermoplastic materials such as rubber material and the encapsulating structure 5 fills up the receiving space 3. The encapsulating structure 5 is used for covering the electronic components 4 so as to fix the electronic components 4 on the substrate 1. Various package methods are provided hereinafter. Please refer to FIG. 1 and FIGS. 2A to 2B, the first method of the first embodiment of the package structure is shown. The first method has the following steps.

Step 1 is mounting the electronic components 4 on the substrate 1. The electronic components 4 is mounted on the substrate 1 by a surface mounting (SMT) method, but not restricted thereby.

Step 2 is forming a frame 2 on the substrate 1. The frame 2 is formed on the substrate 1 by an insert-molding method, but not restricted thereby. The frame 2 can be aligned with periphery edges of the substrate 1, or can extend to sides or bottom of the substrate 2 so that the electronic components 4 are received in the receiving space 3 which is formed by the substrate 1 and the frame 2.

Please refer to FIG. 2A, the substrate 1 is provided and there are circuits formed on the substrate 1. The electronic components 4 are mounted on the contacting pads 100 of the substrate 1 in the step 1. In other words, the electronic components 4 are electrically connected to the circuits on the substrate 1 by the contacting pads 100 to achieve the electric functions. On the other hand, the electronic components 4 can include components with various sizes.

Please refer to FIG. 2B; the frame 2 is formed on the substrate 1 by an insert-molding method. The frame 2 stands on the substrate 1 upwardly and the frame 2 is aligned with periphery edges of the substrate 1. The receiving space 3 is defined with the frame 2 and the substrate 1 and the electronic components 4 are accommodated inside the receiving space 3. The height of each electronic component 4 is lower than that of the frame 2. Therefore, the electronic components 4 which are received in the receiving space 3 can be protected by the frame 2. In another embodiment, the frame 2 can be formed to extend on the sides of the substrate 1 and partially cover the sides of the substrate 1. Alternatively, the frame 2 can be formed to extend on the bottom of the substrate 1.

Therefore, the frame 2 can be fixed on the substrate 1 because of the insert-molding method. The disassembling problem of traditional gluing connection of the frame 2 and the substrate 1 can be solved. Furthermore, the method of the present invention has optimized procedures, high manufacturing yield, improved manufacturing efficiency and low manufacturing cost.

The second method of the first embodiment of the package structure is introduced. The difference of the second method with the above-mentioned first method is that the sequence of the step 1 and step 2 is reversed. In other words, the frame 2 can be formed on the substrate 1 first and the receiving space 3 is defined with the frame 2 and the substrate 1 (as shown in FIG. 2C). Then, the electronic components 4 are mounted on the substrate 1. The other features of the second method are similar with the above-mentioned first method.

An encapsulating structure 5 is formed after the last step of the above-mentioned first or second methods to cover the electronic components 4 entirely. The above-described encapsulating structure 5 and the process thereof are familiar to those skilled in this art.

Moreover, the conductive hole portions 22 are formed by etching and/or electroplating processes (Step 3), and the conductive hole portions 22 are electrically connected to the circuits of the substrate 1, as shown in FIG. 1.

In the present invention, the substrate 1 and the frame 2 are provided for constructing the receiving space 3 so as to receive the electronic components 4. Therefore, it is not necessary to excavate a hole on the substrate 1. In other words, the method of the present invention is more simplified than the traditional method. On the other hand, the thickness of the substrate 1 and the material cost can be decreased. Furthermore, the electronic components 4 are received inside the receiving space 3 so that the electronic components 4 are protected from disconnection due to the collision of usage or installation. The electronic components 4 are also protected from contamination of welding material in the welding process and the supporting strength is improved. Therefore, the frame 2 is used for directly packaging the electronic components 4 and the frame 2 is partially etched in order to form the electrical connection. The manufacturing cost and time are decreased.

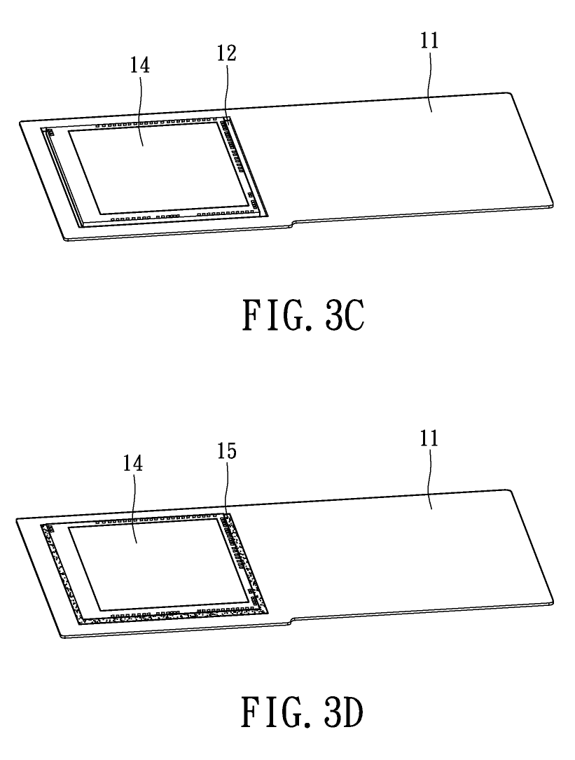

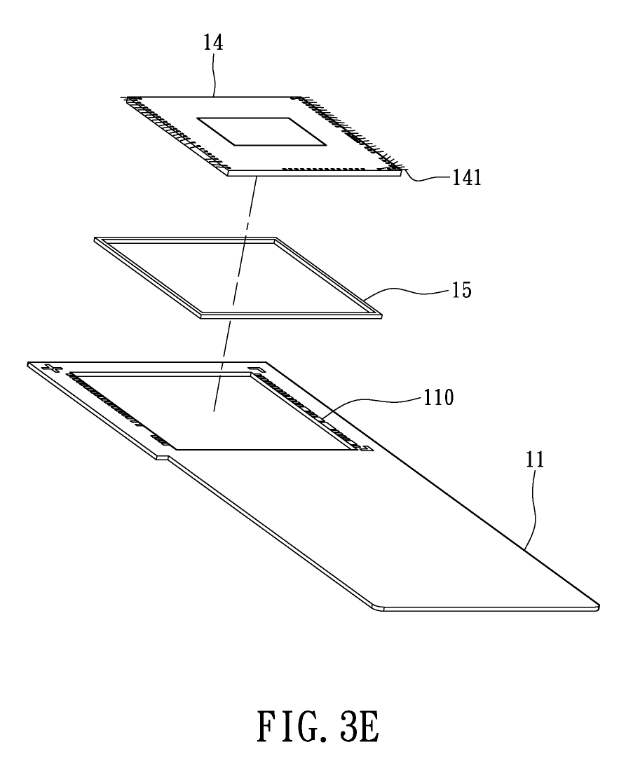

Please refer to FIGS. 3A to 3E; the package method of the second embodiment has the following steps. The substrate 1 of the embodiment can be a flex printed circuit (FPC) board or a rigid-flex board.

Step (1) is forming a receiving hole 12 on a substrate 11, as shown in FIG. 3A.

Step (2) is providing the substrate 11 and the electronic component(s) 14 on a mold 10, and the substrate 11 and the electronic component 14 are fixed on the mold 10 by the positioning pieces 101 of the mold 10. The electronic components 14 are accommodated in the receiving hole 12. On the other hand, the electronic components 14 can be various components or have various sizes. The amount of the electronic components 14 is not limited, but there in one electronic component 14 shown in FIG. 3B.

Step (3) is forming a frame 15 to fix the electronic component 14 in the receiving hole 12 of the substrate 11 as shown in FIGS. 3D and 3E. In the embodiment, the frame 15 is formed by an insert-molding method, but not restricted thereby.

In detail, Step (1) is applied for forming the receiving hole 12 on the substrate 11 by an excavating method. The size of the receiving hole 12 is larger than that of the electronic component 14 so that the electronic component 14 can be accommodated inside the receiving hole 12. Preferably, there is gap between the electronic component 14 and the substrate 11 for packaging and fixing the electronic component 14 with the substrate 11. The size of the receiving hole 12 can be adjusted depending on the amount and the sizes of the electronic components 14.

Step (2) is applied for disposing the substrate 11 and the electronic component 14 on the mold 10, and the electronic component 14 is accommodated inside the receiving hole 12 of the substrate 11. In other words, substrate 11 is disposed entirely around the electronic component 14. The height of the electronic component 14 is higher than that of the substrate 11. A traditional harder board is not necessary for carrying the electronic component 14. Therefore, the electronic component 14 is prevented from the contamination of welding material, and the thickness of the package structure can be reduced. In the embodiment, the thickness of the electronic component 14 is equal to that of the package structure.

Step (3) is forming a frame 15 around the periphery of the electronic component 14 so as to fix the electronic component 14 in the receiving hole 12. In the embodiment, the frame 15 is made of a package material by the insert-molding method. Then, the electronic component 14 is connected to the contacting pads 110 of the substrate 11 via bonding wires 141, as shown in FIG. 3E.

According to the above-mentioned steps, the package structure of printed circuit board is provided. The package structure includes a substrate 11 and at least one electronic component 14. The substrate 11 has a receiving hole 12 therein and the electronic component 14 disposed in the receiving hole 12. A frame 15 is formed to fix the electronic component 14 with the substrate 11.

Therefore, the flex board is used to be the substrate 11 and is applied for fixing the electronic component 14. Therefore, the traditional harder board is omitted so that the row material and the manufacturing cost are reduced. Moreover, the thickness of the package structure is decreased.

The above-mentioned descriptions represent merely the preferred embodiment of the present invention, without any intention to limit the scope of the present invention thereto. Various equivalent changes, alternations, or modifications based on the claims of present invention are all consequently viewed as being embraced by the scope of the present invention.

What is claimed is:

1. A package structure of printed circuit board, comprising: a substrate and a frame, the frame disposed on the substrate to form a receiving space, and a plurality of electronic components mounted on the substrate and received inside the receiving space.

2. The package structure of printed circuit board according to claim 1, wherein the frame is aligned to the peripheral edges of the substrate.

3. The package structure of printed circuit board according to claim 1, wherein the frame extends on the sides of the substrate and partially covers the sides of the substrate, or the frame extends to a bottom of the substrate.

4. The package structure of printed circuit board according to claim 1, wherein the frame further has a plurality of conductive hole portions, and the conductive hole portions are connected electrically to the substrate.

5. The package structure of printed circuit board according to claim 1, wherein a height of the frame is higher than or equal to a height of each of the electronic components.

6. The package structure of printed circuit board according to claim 1, wherein the substrate is a printed circuit board, a FPC, a rigid-flex board, or a ceramic board.

7. The package structure of printed circuit board according to claim 1, wherein the frame is made of thermoplastic materials.

8. A package structure of printed circuit board, comprising: a substrate and at least one electronic component, the substrate having a receiving hole therein, the electronic component disposed in the receiving hole and fixed to the substrate via a frame.

9. The package structure of printed circuit board according to claim 8, wherein the frame is made of packaging material, and the packaging material covers the electronic component by an insert-molding method.

10. The package structure of printed circuit board according to claim 8, wherein the substrate is a FPC, or a rigid-flex board.

11. A package method of printed circuit board, comprising steps of:
step 1: mounting a plurality of electronic components on a substrate; and
step 2: forming a frame on the substrate, the frame being aligned with periphery edges of the substrate, or extending to sides or bottom of the substrate so that the electronic components are received in a receiving space formed by the substrate and the frame.

12. The package method of printed circuit board according to claim 11, wherein the steps 1 through 2 are performed in reverse sequence.

13. The package method of printed circuit board according to claim 11, further comprising a step 3: forming a plurality of conductive hole portions on sides of the frame via etching/electro-plating processes after step 2.

14. A package method of printed circuit board, comprising steps of:
step 1: forming a receiving hole on a substrate;
step 2: providing the substrate and at least one electronic component on a mold;
step 3: forming a frame to fix the electronic component in the receiving hole of the substrate.

15. The package method of printed circuit board according to claim 14, wherein the substrate is a FPC, or a rigid-flex board.
